(19) United States
(12) Patent Application Publication
(10) Pub. No.: US 2005/0090088 A1
(43) Pub. Date: Apr. 28, 2005

(54) Method for forming a word line spacer with good square profile

(76) Inventor: Shuang Hsun Chang, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/972,453

(22) Filed: Oct. 26, 2004

(30) Foreign Application Priority Data
Oct. 27, 2003 (CN) 200310108194.9

(51) Int. Cl. H01L 21/336; H01L 21/3205; H01L 21/4763

(52) U.S. Cl. 438/595

(57) ABSTRACT

A method for forming a word line spacer with good square profile comprising providing a semiconductor substrate having a patterned oxide layer, a polysilicon layer, and an oxide layer in sequence formed thereon. The four step etch sequence comprises a Breakthrough Etch (BT), a Main Etch (ME), an Oxide Etch, and an Overall Etch (OE) in order to complete the fabrication of word line spacer. The present invention provides a method for forming a word line spacer with good square profile, which removes an undesireable fence profile in order to form a word line spacer with good square profile.

### BACKGROUND OF THE INVENTION

1. Field of the Invention

The present invention relates to a method for fabricating a sidewall spacer in semiconductor processing, and more particularly, to a method for forming a word line spacer with good square profile.

2. Description of the Prior Art

Semiconductor device performance continues to be improved by virtue of reductions in device dimensions and by increasing device packaging densities.

However as the size of devices shrinks, each device in the chip needs to be properly insulated and isolated in order to obtain better device performance. An isolation is formed between various devices to ensure that a good effectively isolation is maintained in order to shrink the isolation area, thereby allowing the chip to contain more devices. In addition to shallow trench isolation (STI) as an isolation device, spacers are often used and formed on the substrate around the gate (word line) by using insulating materials. This prevents leakage current from the conduction between the gate and the gate/drain. The preferred design is that the height of the spacer is the same as the height of the gate, thereby preventing the conduction between the gate and the gate/drain.

Spacer are not only used as isolation devices, but are also used as a polysilicon spacer. In the conventional process, the polysilicon layer is etched to form a polysilicon spacer, as shown in FIG. 1a. After defining the active area of the semiconductor substrate 10, a patterned oxide layer 12, a polysilicon layer 14 and an oxide layer 16 are formed in sequence. The etching step comprises a Main Etch (ME) step to etch the oxide layer 16 by dry etching. The polysilicon layer 14 is then etched to remove the oxide layer 16 and a portion of the polysilicon layer 14, as shown in FIG. 1b, thereby forming the polysilicon spacer 18 on the sidewall of the patterned oxide layer 12 and exposing the upper surface of the semiconductor substrate 10.

However, the above-mentioned method of fabricating the polysilicon spacer 18 easily causes a fence structure 20 as shown in FIG. 1b. This fence structure 10 may act as a particle source, thereby causing an effect in the subsequent deposition process of thin film, resulting in the fabricated device having critical defects. Additional, in order to eliminate the redundant polysilicon layer 14 on the semiconductor substrate 10 and the particles produced from the etching, after completing the Main Etch (ME), an Overall Etch is usually performed. However, the height of the upper surface of the polysilicon spacer 18 is usually reduced. Even a portion of the upper sidewall of the patterned oxide layer is exposed.

Therefore, the present invention provides a method for forming a word line with good square profile, which increases the yield of IC processing.

### SUMMARY OF THE INVENTION

The present invention provides a method for forming a word line spacer with good square profile, which removes the fence profile in order to form a word line spacer with good square profile.

The present invention also provides a method for forming a word line spacer, which effectively controls the width, the height and the shape of the defined word line spacer so as to obtain a word line spacer with good square profile and increases the yield of IC processing.

These objects are accomplished by providing a semiconductor substrate having a patterned oxide layer, a polysilicon layer, and an oxide layer in sequence formed thereon. A breakthrough step is performed by using a high selective ratio of oxide to polysilicon in order to remove a portion of the oxide layer. A Main Etch is then performed to etch the polysilicon layer and a bit of the oxide layer until the polysilicon layer on the semiconductor substrate becomes a thin film, thereby forming a fence structure on the projecting corner of the oxide layer. An Oxide Etch is then performed to isotropically etch to remove the fence structure projecting from the profile of the polysilicon layer in order to form an aciform corner of the polysilicon layer. An Overall Etch is performed to remove the remaining polysilicon oxide layer on the patterned oxide layer, resulting in the remaining polysilicon layer 36 having word line spacers with a square profile on two sidewalls of the patterned oxide layer.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1a and FIG. 1b are sectional diagrams illustrating a word line spacer according to a conventional process; and

FIGS. 2a through 2e are sectional diagrams illustrating a word line spacer according to a preferred embodiment of the present invention.

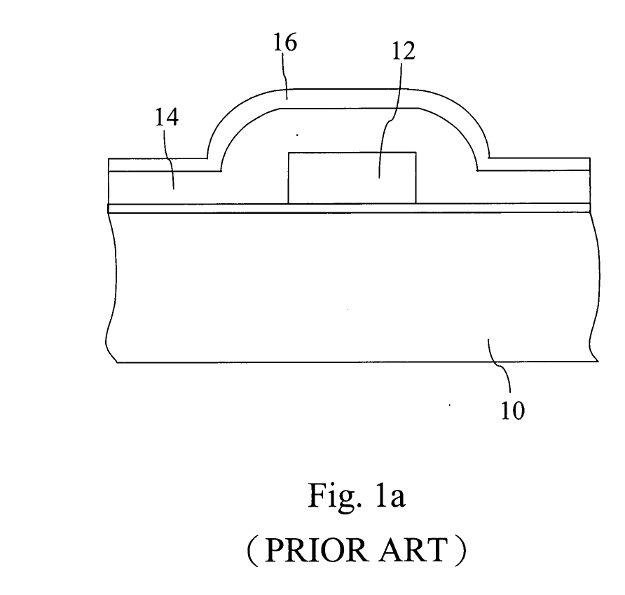

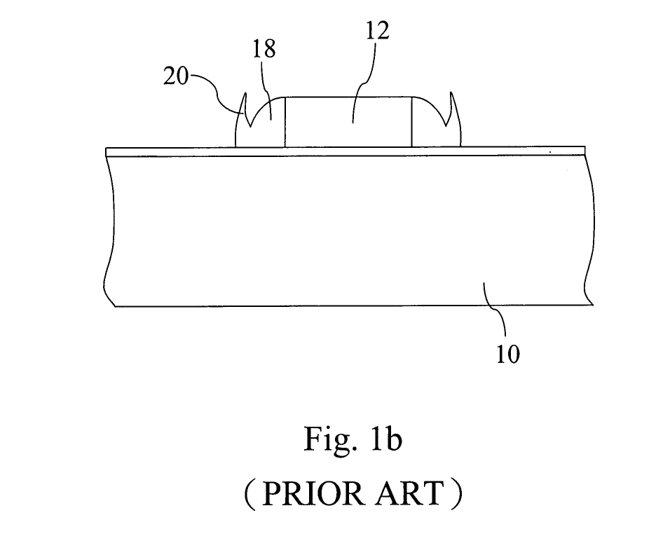

### DETAILED DESCRIPTION OF THE PREFERRED EMBODIMENTS

Since a fence-like structure is easily formed on the spacer edge of the polysilicon spacer, this fence structure may act as a particle source, thereby causing effects in the subsequent deposition process of thin film, resulting in the fabricated device having critical defects. Therefore, the present invention provides a method for forming a word line spacer, which removes the formed fence profile in order to form a word line spacer with good square profile.

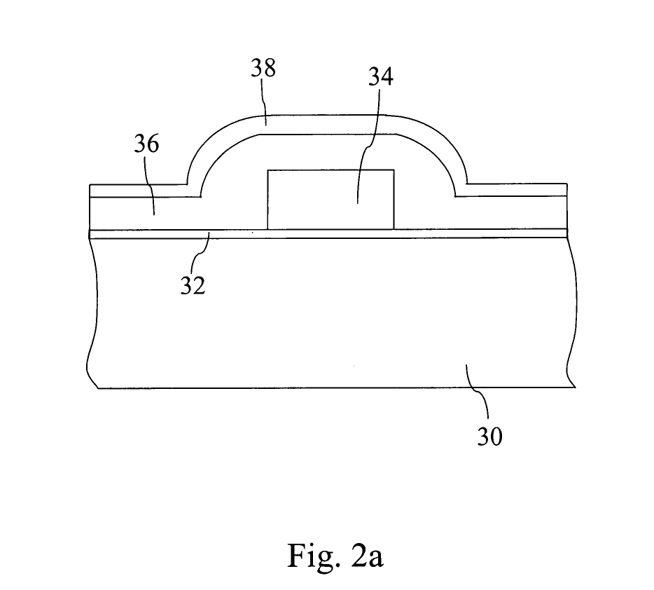

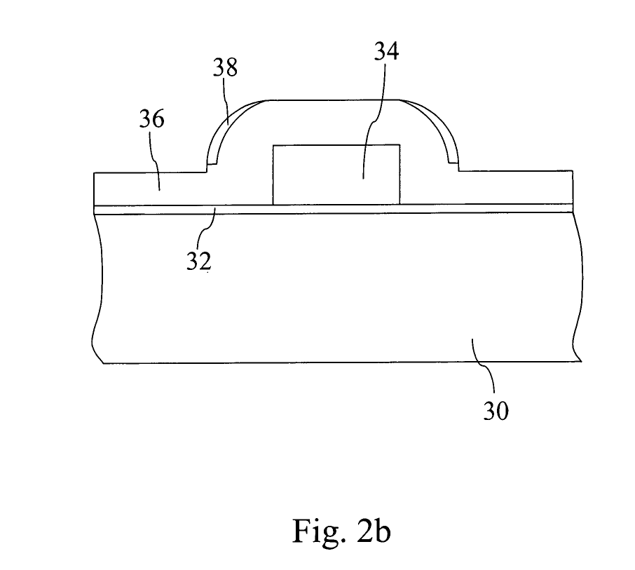

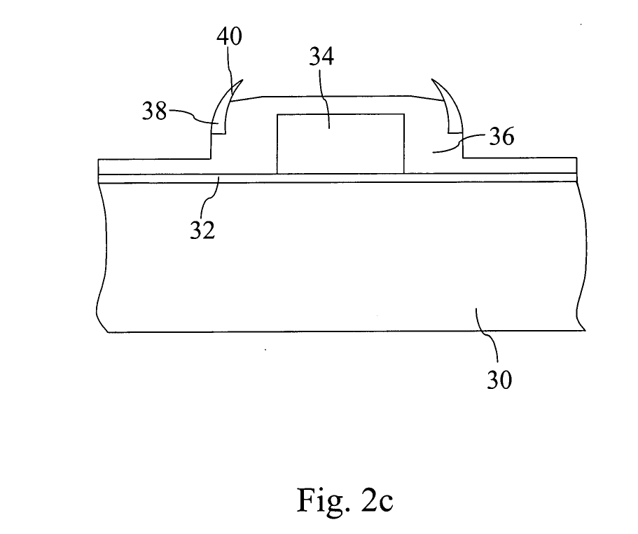

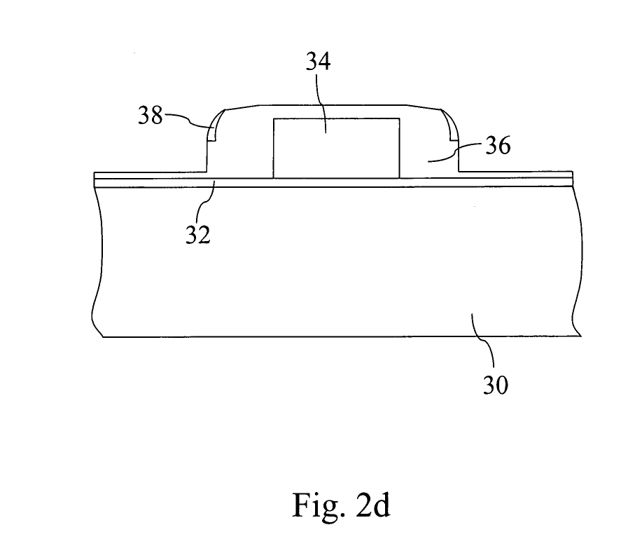

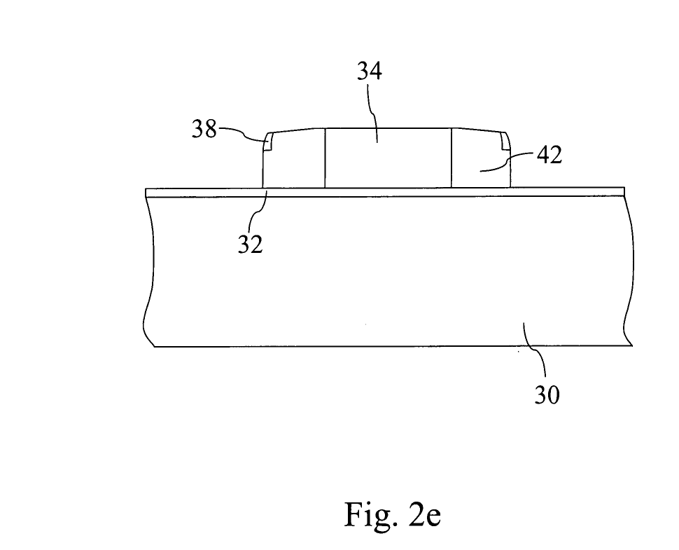

As shown in FIG. 2a, a semiconductor substrate 30 having a <100> lattice is provided. In general, semiconductor materials, such as gallium arsenide or silicon-on-insulator (SOI), are used as this semiconductor substrate 30. The surface properties of the semiconductor substrate will not cause any effect in the present invention.

Next, a pad oxide layer 32 is deposited on the surface of the semiconductor substrate 30. The material of the pad oxide layer 32 is usually silicon oxide. A defined and patterned oxide layer 34 is formed on the surface of the semiconductor substrate 30 by using a photolithography process. A polysilicon layer 36 is then deposited on the semiconductor substrate 30 by Chemical Vapor Deposition (CVD) to cover the patterned oxide layer 34 and the pad oxide layer 32. An oxide layer 38 is formed on the surface of the polysilicon layer 36 by Chemical Vapor Deposition, thermal oxidation or other proper process.

Next, the four step etch is performed. A Breakthrough etch is performed firstly. A portion of the surface of the oxide layer 38 is removed by using high ion bombardment with a high selective ratio of oxide to polysilicon in order to form the structure as shown in FIG. 2b. The portion of the oxide layer 38 can also be removed by using wet etching or dry etching.

After completing the Breakthrough etch, a Main Etch step is then performed. The semiconductor substrate 30 is etched by wet etching or dry etching to remove a portion of the polysilicon layer 36 and a bit of the oxide layer 38, as shown in FIG. 2c, until the polysilicon layer 36 on the semiconductor substrate 30 becomes a thin film and the oxide layer 38 on the projecting corner becomes a fence structure. The remained oxide layer 38 on the corner is used as a liner oxide for a vertical etch of the spacer. This is beneficial for the subsequent etch step in order to maintain a good height and width profile.

Next, an Oxide Etch Step is performed. The fence structure 40 is isotropically etched by a etching with an etch ratio of the oxide larger than the etch ratio of the polysilicon, for example, etching by wet etching, thereby removing the fence structure 40 projecting from the profile of the polysilicon layer 36, as shown in FIG. 2d. A portion of the oxide layer 38 remains. An ion bombardment is then performed on the remained oxide layer 38 by a high bias energy to form an aciform corner of the polysilicon layer 36.

Finally, an Overall Etch Step is performed to remove the remaining polysilicon oxide layer 36 on the patterned oxide layer 34 by using a high selective ratio of polysilicon to oxide, thereby exposing the surface of the patterned oxide layer 36, as shown in FIG. 2e. The remaining polysilicon layer 36 respectively forms the word line spacers 42 with square profile on two sidewalls of the patterned oxide layer 34. In this step, the high selective ratio of polysilicon to oxide maintains a consistent etching in order to control the width of the spacer, thereby obtaining a word line spacer 42 with good square profile.

The four step etch of the present invention typically comprises a Breakthrough Etch (BT), a Main Etch (ME), an Oxide Etch, and an Overall Etch (OE) in order to complete the fabrication of the word line spacer.

Therefore, the present invention provides a method for removing the formed fence structure, which effectively controls the width, the height and the shape of the defined word line spacer so as to obtain a word line spacer with a good square profile and increases the yield of IC processing.

The embodiment above is only intended to illustrate the present invention; it does not, however, to limit the present invention to the specific embodiment. Accordingly, various modifications and changes may be made without departing from the spirit and scope of the present invention as described in the following claims.

1. A method for forming a word line spacer with good square profile, comprising:
forming an patterned oxide layer on a semiconductor substrate, having a polysilicon layer and an oxide layer formed thereon;
performing a Breakthrough Etch to remove a portion of the oxide layer by using a high selective ratio of oxide to polysilicon;
performing a Main Etch to etch the polysilicon layer and a part of the oxide layer until the polysilicon layer on the semiconductor substrate becomes a thin film and a projecting corner of the oxide layer becomes a fence structure;
performing an Oxide Ecth to isotropically etch the fence structure of the oxide layer in order to remove the fence structure projecting from the polysilicon layer to form an aciform corner of the polysilicon layer; and
performing an Overall Etch to remove the remaining polysilicon oxide layer on the patterned oxide layer, wherein the remaining polysilicon layer respectively forms word line spacers with square profiles on two sidewalls of the patterned oxide layer.

2. The method for forming a word line spacer with good square profile of claim 1, wherein in performing the Breakthrough Etch, the oxide layer is removed by using a high ion bombardment.

3. The method for forming a word line spacer with good square profile of claim 1, wherein the polysilicon layer is formed by Chemical Vapor Deposition.

4. The method for forming a word line spacer with good square profile of claim 1, wherein the oxide layer is formed by Chemical Vapor Deposition of thermal oxidation.

5. The method for forming a word line spacer with good square profile of claim 1, wherein in performing the Oxide Etch, the fence structure projecting from the polysilicon layer is removed by etching with an etch ratio of the oxide larger than the etch ratio of the polysilicon.

6. The method for forming a word line spacer with good square profile of claim 1, wherein the Oxide etch is performed by wet etching.

7. The method for forming a word line spacer with good square profile of claim 1, wherein in performing the Oxide etch, further performing an ion bombardment by a high bias energy to form an aciform corner of the polysilicon layer.

8. The method for forming a word line spacer with good square profile of claim 1, wherein in performing the Breakthrough Etch, the oxide layer is removed by wet or dry etching.

9. The method for forming a word line spacer with good square profile of claim 1, wherein the Main Etch is performed by wet etching or dry etching.

10. The method for forming a word line spacer with good square profile of claim 1, wherein the Overall Etch step is performed to remove the remaining polysilicon oxide layer by using a high selective ratio of polysilicon to oxide.

11. The method for forming a word line spacer with good square profile of claim 1, further comprising forming a pad oxide on the surface of the semiconductor substrate, wherein the patterned oxide layer is positioned on the pad oxide layer.
